(19) United States
(12) Patent Application Publication
(10) Pub. No.: US 2012/0194975 A1
(43) Pub. Date: Aug. 2, 2012

(54) HAND-HELD TABLET ELECTRONIC DEVICE WITH SLANTED FRONT FACE

(75) Inventors: CHENG-HAO CHOU, Tu-Cheng (TW); CHIANG-KUO TANG, Tu-Cheng (TW); PING-CHOU CHEN, Tu-Cheng (TW); BING-FENG LONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/180,473

(22) Filed: Jul. 11, 2011

(30) Foreign Application Priority Data
Jan. 28, 2011 (CN) 201110031092.6

(51) Int. Cl. H05K 7/00

(52) U.S. Cl. 361/679.01

(57) ABSTRACT

A hand-held tablet n electronic device includes a display screen, a frame. The frame surrounding the display screen includes two parallel sidewalls on opposite sides of the display screen, each of the sidewall includes a front face adjacent to the display screen and slightly slanted toward the display screen, an angle between each of the front faces and a main plane of the display screen being in a range from 1 to 3 degrees.

### BACKGROUND

1. Technical Field

The present disclosure relates to a hand-held tablet electronic device with slanted front face.

2. Description of the Related Art

Electronic devices such as digital photo frames and tablet computers include a frame with a horizontal front surface. When the electronic device is very slim, the electronic device may slip from the hand of the user.

Therefore, there is room for improvement within the art.

### BRIEF DESCRIPTION OF THE DRAWINGS

The components in the drawings are not necessarily drawn to scale, the emphasis instead being placed upon clearly illustrating the principles of a hand-held tablet electronic device with slanted front face. Moreover, in the drawings, like reference numerals designate corresponding parts throughout the several views.

FIG. 1 is a schematic view of a hand-held tablet electronic device with inclined surfaces.

FIG. 2 is a cross-sectional view taken along the line II-II of FIG. 1.

### DETAILED DESCRIPTION

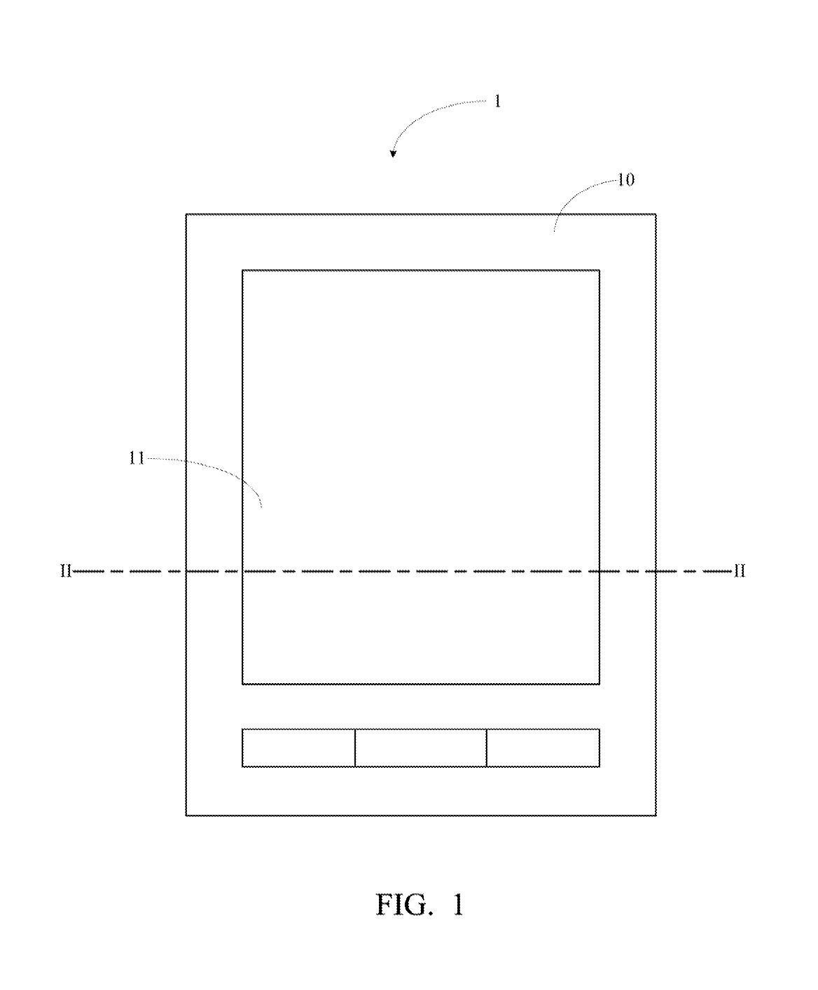

Referring to FIG. 1, a hand-held tablet electronic device 1 includes a frame 10 and a display screen 11. The frame 10 surrounding the display screen 11.

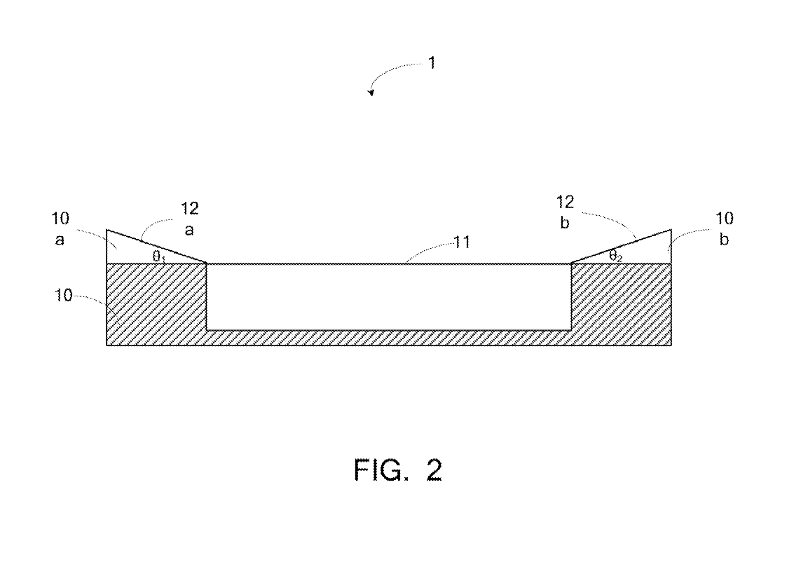

Referring to FIG. 2, the frame 10 includes two parallel sidewalls 10a and 10b on opposite sides of the display screen 11, each of the sidewalls 10a and 10b includes a front face 12 adjacent to the display screen 11 and slightly slanted toward the display screen 11. In the embodiment, the front face 12 is divided by the display screen 11 into two front faces 12a and 12b, and the front face 12a is the front surface of the parallel sidewall 10a and the front face 12b is the front surface of the parallel sidewall 10b. In an alternative embodiment, the front faces 12a or 12b is only a portion of the front surface of the parallel sidewall 10a or 10b. The front face 12a is tilted an angle θ₁ with respect to the display screen 11, and the front face 12b is tilted an angle θ₂ with respect to the display screen 11. In the embodiment, the angle θ₁ is equal to the angle θ₂, and are all about 1 degree. In an alternative embodiment, the angles θ₁ and angle θ₂, can be any value within 1 to 3 degrees. Because of the front face 12, the outside edges of the parallel sidewalls 10a and 10b are higher than the display screen 11.

In the embodiment, the front face 12 include raised patterns formed thereon for increasing gripping strength between a the fingers of a user and the surfaces 12a and 12b, which can prevent slippage of the hand-held tablet electronic device 1 from the hand of the user.

It is understood that the present disclosure may be embodied in other forms without departing from the spirit thereof. Thus, the present examples and embodiments are to be considered in all respects as illustrative and not restrictive, and the disclosure is not to be limited to the details given herein.

What is claimed is:

1. A hand-held tablet electronic device comprising:
a display screen; and
a frame surrounding the display screen, the frame including two parallel sidewalls on opposite sides of the display screen, each of the sidewall including a front face adjacent to the display screen and slightly slanted toward the display screen, an angle between each of the front faces and a main plane of the display screen being in a range from 1 to 3 degrees.

2. The electronic device as recited in claim 1, wherein the front faces include raised patterns formed thereon for increasing gripping strength.

3. The electronic device as recited in claim 1, wherein the sidewalls are parallel to a lengthwise direction the electronic device.
